(19) United States
(12) Patent Application Publication
(10) Pub. No.: US 2021/0376797 A1
(43) Pub. Date: Dec. 2, 2021

(54) LOW-NOISE AMPLIFIER SUPPORTING MULTI CARRIER OPERATIONS

(71) Applicant: Apple Inc., Cupertino, CA (US)

(72) Inventors: Mohammed ALAM, Chandler, AZ (US); Yiwen CHEN, Chandler, AZ (US); Ricardo FERNANDEZ, Scottsdale, AZ (US); Dong-Jun YANG, Chandler, AZ (US)

(21) Appl. No.: 16/976,635

(22) PCT Filed: Mar. 30, 2018
(86) PCT No.: PCT/US2018/025314

§ 371 Date: Aug. 28, 2020

(51) Int. Cl. H03F 1/02; H03F 1/52; H03F 3/195; H03F 3/30; H03F 3/72; H03F 3/24; H03F 1/56; H03F 3/68

(52) U.S. Cl. CPC H03F 1/0277; H03F 2200/222; H03F 3/195; H03F 3/3023; H03F 3/72; H03F 3/245; H03F 1/56; H03F 3/68; H03F 2200/294; H03F 2200/451; H03F 2200/111; H03F 2200/27; H03F 2203/30081; H03F 2203/30111; H03F 2203/30114; H03F 2203/7215; H03F 2203/7236; H03F 1/523

(57) ABSTRACT

A radio-frequency (RF) amplifier circuit facilites carrier-aggregation (CA) operation in a wireless communication network. A first amplifier subcircuit is coupled to an input node, and a second amplifier subcircuit is coupled to the input node. An amplifier subcircuit selector is to selectively enable operation of the first amplifier subcircuit, the second amplifier subcircuit, or the first and the second amplifier subcircuits together, in response to a selection indication. A reactive coupling network is arranged to selectively adjust the input impedance at the input node in response to the selection indication to reduce the input impedance variation.

### TECHNICAL FIELD

Aspects of the present subject matter pertain to wireless communications. Some examples relate to wireless networks including 3GPP (Third Generation Partnership Project) networks, 3GPP LTE (Long Term Evolution) networks, 3GPP LTE-A (LTE Advanced) networks, and fifth-generation (5G) networks. Other examples relate to Wi-Fi wireless local area networks (WLANs). Further examples are more generally applicable outside the purview of LTE and Wi-Fi networks. Aspects are directed to low-noise amplifier (LNA) circuitry for use in a radio transceiver.

### BACKGROUND

Mobile data usage continues growing exponentially at a rate of nearly doubling year-after-year, and this trend is expected to continue. Although recent advances in cellular technology have made improvements in the performance and capacity of mobile networks, it is widely thought that such advances will still fall short of accommodating the anticipated demand for mobile data network service.

One approach to increasing mobile network capacity is utilizing multiple carrier frequencies simultaneously or concurrently in an arrangement referred to as carrier aggregation. Carrier aggregation facilitates higher bit rates through the implementation of greater bandwidth. Carrier aggregation may be used within a given frequency band, in which case it is referred to as intra-band carrier aggregation. Intra-band carrier aggregation can be contiguous or non-contiguous. In the contiguous use case, adjacent carrier frequencies are used together. In the non-contiguous use case carrier frequencies are used together for communications between a pair of devices that may be separated by one or more other carrier frequencies which are not used by the communicating pair of devices.

### BRIEF DESCRIPTION OF THE DRAWINGS

In the drawings, which are not necessarily drawn to scale, like numerals may describe similar components in different views. Like numerals having different letter suffixes may represent different instances of similar components. Some aspects are illustrated by way of example, and not limitation, in the following figures of the accompanying drawings.

FIG. 1A is an exemplary block diagram illustrating a system architecture of a network in accordance with some aspects.

FIG. 1B illustrates example components of a device as depicted in FIG. 1A in accordance with some aspects.

FIG. 2 is a diagram illustrating carrier aggregation (CA) operation according to some aspects.

FIG. 3 illustrates communication circuitry according to some aspects.

FIG. 4 illustrates RF circuitry of the communication circuitry of FIG. 3 in greater detail according to some aspects.

FIG. 5 is a block-level schematic diagram illustrating a portion of amplification circuitry of the RF circuitry of FIG. 4 according to some aspects.

FIGS. 6A-6B are simplified schematic diagrams illustrating a reactive coupling network according to various examples.

FIG. 7 is a transistor-level schematic diagram illustrating a switched-LNA arrangement in greater detail according to an aspect.

FIG. 8 is a block-level schematic diagram illustrating some features of a LNA according to an aspect.

FIG. 9 is a transistor-level schematic diagram illustrating an example of a LNA circuit.

FIG. 10 is a block-level schematic diagram illustrating an example LNA arrangement for dynamically-reconfigurable multi-band operation.

FIG. 11 is a transistor-level schematic diagram illustrating an example of a switched-LNA arrangement that features dynamically-configurable multi-band operation.

FIG. 12 is a process flow diagram illustrating an example set of operations to be carried out by a controller of the switched-LNA arrangement of FIG. 5.

FIG. 13 is a process flow diagram illustrating an example set of operations to be carried out by a controller of the multi-band LNA arrangement of FIG. 10.

### DETAILED DESCRIPTION

The following description and the drawings sufficiently illustrate specific aspects to enable those skilled in the art to practice them. A number of aspects are described in the context of 3GPP communication systems and components thereof. It will be understood that principles of the aspects are applicable in other types of communication systems, such as Wi-Fi or Wi-Max networks, Bluetooth or other personal-area networks (PANs), Zigbee or other home-area networks (HANs), wireless mesh networks, and the like, without limitation, unless expressly limited by a corresponding claim.

Given the benefit of the present disclosure, persons skilled in the relevant technologies will be able to engineer suitable variations to implement principles of the aspects in other types of communication systems. For example, it will be understood that a base station or e-Node B (eNB) of a 3GPP context is analogous, generally speaking, to a wireless access point (AP) of a WLAN context. Likewise, user equipment (UE) of a 3GPP context is generally analogous to mobile stations (STAs) of WLANs. Various diverse examples may incorporate structural, logical, electrical, process, and other differences. Portions and features of some examples may be included in, or substituted for, those of other examples. Examples set forth in the claims encompass all presently-known, and after-arising, equivalents of those claims.

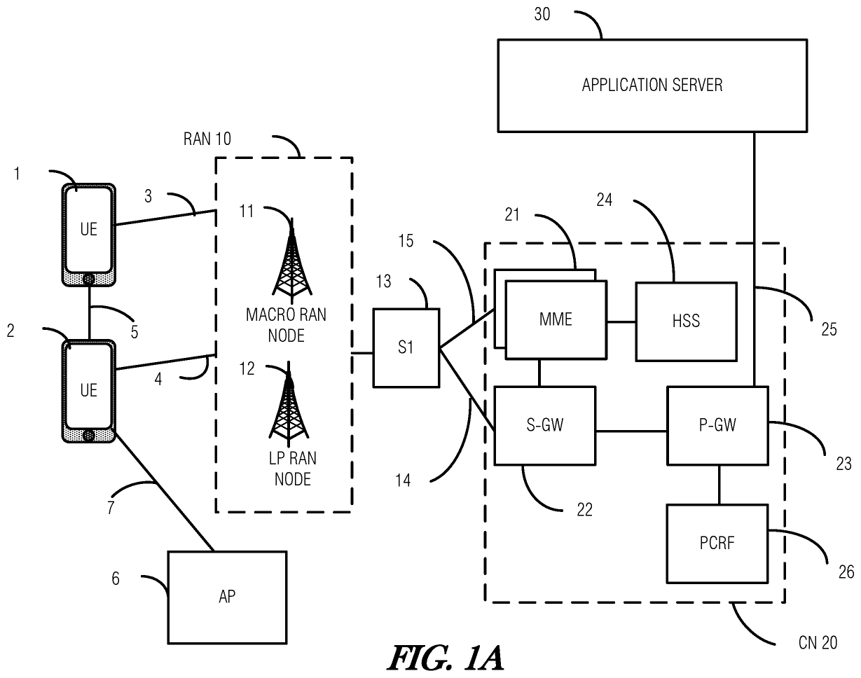

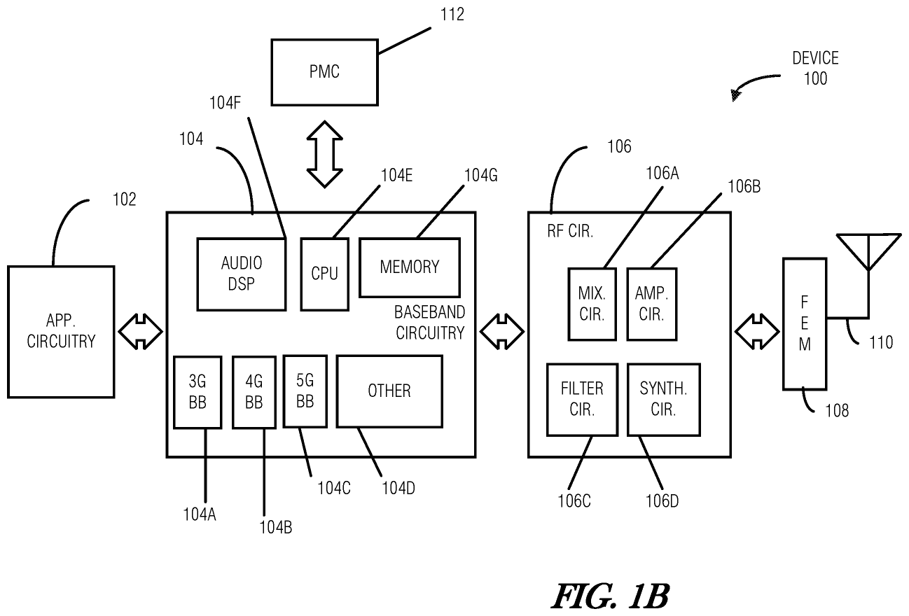

FIG. 1A is an exemplary block diagram illustrating a system architecture of a network in accordance with some aspects. The system as depicted in FIG. 1A includes a user equipment (UE) 1 and a UE 2. The UEs 1 and 2 are illustrated as smartphones (e.g., handheld touchscreen mobile computing devices connectable to one or more cellular networks), but may also comprise any mobile or non-mobile computing device, such as Personal Data Assistants (PDAs), pagers, laptop computers, desktop computers, wireless handsets, or any computing device having a wireless communication capability or interface.

In some aspects, any of the UEs 1 and 2 can comprise an Internet of Things (IoT) UE, which can comprise a network access layer designed for low-power IoT applications utilizing short-lived UE connections. An IoT UE can utilize technologies such as machine-to-machine (M2M) or machine-type communications (MTC) for exchanging data with an MTC server or device via a public land mobile network (PLMN), Proximity-Based Service (ProSe) or device-to-device (D2D) communication, sensor networks, or IoT networks. The M2M or MTC exchange of data may be a machine-initiated exchange of data. An IoT network describes interconnecting IoT UEs, which may include uniquely identifiable embedded computing devices (within the Internet infrastructure), with short-lived connections. The IoT UEs may execute background applications (e.g., keep-alive messages, status updates, etc.) to facilitate the connections of the IoT network.

The UEs 1 and 2 may be configured to connect, e.g., communicatively couple, with a radio access network (RAN) 10—the RAN 10 may be, for example, an Evolved Universal Mobile Telecommunications System (UMTS) Terrestrial Radio Access Network (E-UTRAN), a NextGen RAN (NG RAN), or some other type of RAN. The UEs 1 and 2 utilize connections 3 and 4, respectively, each of which comprises a physical communications interface or layer (discussed in further detail below); in this aspect, the connections 3 and 4 are illustrated as an air interface to enable communicative coupling, and can be consistent with cellular communications protocols, such as a Global System for Mobile Communications (GSM) protocol, a code-division multiple access (CDMA) network protocol, a Push-to-Talk (PTT) protocol, a PTT over Cellular (POC) protocol, a Universal Mobile Telecommunications System (UMTS) protocol, a 3GPP Long Term Evolution (LTE) protocol, a fifth generation (5G) protocol, a New Radio (NR) protocol, and the like.

In this aspect, the UEs 1 and 2 may further directly exchange communication data via a ProSe interface 5. The ProSe interface 5 may alternatively be referred to as a sidelink interface comprising one or more logical channels, including but not limited to a Physical Sidelink Control Channel (PSCCH), a Physical Sidelink Shared Channel (PSSCH), a Physical Sidelink Discovery Channel (PSDCH), and a Physical Sidelink Broadcast Channel (PSBCH).

The UE 2 is shown to be configured to access an access point (AP) 6 via connection 7. The connection 7 can comprise a local wireless connection, such as a connection consistent with any IEEE 802.11 protocol, wherein the AP 6 would comprise a wireless fidelity (WiFi®) router. In this aspect, the AP 6 is shown to be connected to the Internet without connecting to the core network of the wireless system (described in further detail below).

The RAN 10 can include one or more access nodes that enable the connections 3 and 4. These access nodes (ANs) can be referred to as base stations (BSs), NodeBs, evolved NodeBs (eNBs), next Generation NodeBs (gNBs), RAN nodes, and so forth, and can comprise ground stations (e.g., terrestrial access points) or satellite stations providing coverage within a geographic area (e.g., a cell). The RAN 10 may include one or more RAN nodes for providing macrocells, e.g., macro RAN node 11, and one or more RAN nodes for providing femtocells or picocells (e.g., cells having smaller coverage areas, smaller user capacity, or higher bandwidth compared to macrocells), e.g., low power (LP) RAN node 12.

Any of the RAN nodes 11 and 12 can terminate the air interface protocol and can be the first point of contact for the UEs 1 and 2. In some aspects, any of the RAN nodes 11 and 12 can fulfill various logical functions for the RAN 10 including, but not limited to, radio network controller (RNC) functions such as radio bearer management, uplink and downlink dynamic radio resource management and data packet scheduling, and mobility management.

In accordance with some aspects, the UEs 1 and 2 can be configured to communicate using Orthogonal Frequency-Division Multiplexing (OFDM) communication signals with each other or with any of the RAN nodes 11 and 12 over a multicarrier communication channel in accordance various communication techniques, such as, but not limited to, an Orthogonal Frequency-Division Multiple Access (OFDMA) communication technique (e.g., for downlink communications) or a Single Carrier Frequency Division Multiple Access (SC-FDMA) communication technique (e.g., for uplink and ProSe or sidelink communications), although the scope of the aspects is not limited in this respect. The OFDM signals can comprise a plurality of orthogonal subcarriers.

In some aspects, a downlink resource grid can be used for downlink transmissions from any of the RAN nodes 11 and 12 to the UEs 1 and 2, while uplink transmissions can utilize similar techniques. The grid can be a time-frequency grid, called a resource grid or time-frequency resource grid, which is the physical resource in the downlink in each slot. Such a time-frequency plane representation is a common practice for OFDM systems, which makes it intuitive for radio resource allocation. Each column and each row of the resource grid corresponds to one OFDM symbol and one OFDM subcarrier, respectively. The duration of the resource grid in the time domain corresponds to one slot in a radio frame. The smallest time-frequency unit in a resource grid is denoted as a resource element. Each resource grid comprises a number of resource blocks, which describe the mapping of certain physical channels to resource elements. Each resource block comprises a collection of resource elements; in the frequency domain, this may represent the smallest quantity of resources that currently can be allocated. There are several different physical downlink channels that are conveyed using such resource blocks.

The physical downlink shared channel (PDSCH) may carry user data and higher-layer signaling to the UEs 1 and 2. The physical downlink control channel (PDCCH) may carry information about the transport format and resource allocations related to the PDSCH channel, among other things. It may also inform the UEs 1 and 2 about the transport format, resource allocation, and H-ARQ (Hybrid Automatic Repeat Request) information related to the uplink shared channel. Typically, downlink scheduling (assigning control and shared channel resource blocks to the UE 2 within a cell) may be performed at any of the RAN nodes 11 and 12 based on channel quality information fed back from any of the UEs 1 and 2. The downlink resource assignment information may be sent on the PDCCH used for (e.g., assigned to) each of the UEs 1 and 2.

The PDCCH may use control channel elements (CCEs) to convey the control information. Before being mapped to resource elements, the PDCCH complex-valued symbols may first be organized into quadruplets, which may then be permuted using a sub-block interleaver for rate matching. Each PDCCH may be transmitted using one or more of these CCEs, where each CCE may correspond to nine sets of four physical resource elements known as resource element groups (REGs). Four Quadrature Phase Shift Keying (QPSK) symbols may be mapped to each REG. The PDCCH can be transmitted using one or more CCEs, depending on the size of the downlink control information (DCI) and the channel condition. There can be four or more different PDCCH formats defined in LTE with different numbers of CCEs (e.g., aggregation level, L=1, 2, 4, or 8).

Some aspects may use concepts for resource allocation for control channel information that are an extension of the above-described concepts. For example, some aspects may utilize an enhanced physical downlink control channel (EPDCCH) that uses PDSCH resources for control information transmission. The EPDCCH may be transmitted using one or more enhanced the control channel elements (ECCEs). Similar to above, each ECCE may correspond to nine sets of four physical resource elements known as an enhanced resource element groups (EREGs). An ECCE may have other numbers of EREGs in some situations.

The RAN 10 is shown to be communicatively coupled to a core network (CN) 20 -via an S1 interface 13. In aspects, the CN 20 may be an evolved packet core (EPC) network, a NextGen Packet Core (NPC) network, or some other type of CN. In this aspect, the S1 interface 13 is split into two parts: the S1-U interface 14, which carries traffic data between the RAN nodes 11 and 12 and the serving gateway (S-GW) 22, and the S1-mobility management entity (MME) interface 15, which is a signaling interface between the RAN nodes 11 and 12 and MMEs 21.

In this aspect, the CN 20 comprises the MMES 21, the S-GW 22, the Packet Data Network (PDN) Gateway (P-GW) 23, and a home subscriber server (HSS) 24. The MMES 21 may be similar in function to the control plane of legacy Serving General Packet Radio Service (GPRS) Support Nodes (SGSN). The MMES 21 may manage mobility aspects in access such as gateway selection and tracking area list management. The HSS 24 may comprise a database for network users, including subscription-related information to support the network entities' handling of communication sessions. The CN 20 may comprise one or several HSSs 24, depending on the number of mobile subscribers, on the capacity of the equipment, on the organization of the network, etc. For example, the HSS 24 can provide support for routing/roaming, authentication, authorization, naming/addressing resolution, location dependencies, etc.

The S-GW 22 may terminate the Si interface 13 towards the RAN 10, and routes data packets between the RAN 10 and the CN 20. In addition, the S-GW 22 may be a local mobility anchor point for inter-RAN node handovers and also may provide an anchor for inter-3GPP mobility. Other responsibilities may include lawful intercept, charging, and some policy enforcement.

The P-GW 23 may terminate an SGi interface toward a PDN. The P-GW 23 may route data packets between the EPC network 23 and external networks such as a network including the application server 30 (alternatively referred to as application function (AF)) via an Internet Protocol (IP) interface 25. Generally, the application server 30 may be an element offering applications that use IP bearer resources with the core network (e.g., UMTS Packet Services (PS) domain, LTE PS data services, etc.). In this aspect, the P-GW 23 is shown to be communicatively coupled to an application server 30 via an IP communications interface 25. The application server 30 can also be configured to support one or more communication services (e.g., Voice-over-Internet Protocol (VoIP) sessions, PTT sessions, group communication sessions, social networking services, etc.) for the UEs 1 and 2 via the CN 20.

The P-GW 23 may further be a node for policy enforcement and charging data collection. Policy and Charging Enforcement Function (PCRF) 26 is the policy and charging control element of the CN 20. In a non-roaming scenario, there may be a single PCRF in the Home Public Land Mobile Network (HPLMN) associated with a UE's Internet Protocol Connectivity Access Network (IP-CAN) session. In a roaming scenario with local breakout of traffic, there may be two PCRFs associated with a UE's IP-CAN session: a Home PCRF (H-PCRF) within a HPLMN and a Visited PCRF (V-PCRF) within a Visited Public Land Mobile Network (VPLMN). The PCRF 26 may be communicatively coupled to the application server 30 via the P-GW 23. The application server 30 may signal the PCRF 26 to indicate a new service flow and select the appropriate Quality of Service (QoS) and charging parameters. The PCRF 26 may provision this rule into a Policy and Charging Enforcement Function (PCEF) (not shown) with the appropriate traffic flow template (TFT) and QoS class of identifier (QCI), which commences the QoS and charging as specified by the application server 30.

FIG. 1B illustrates example components of a device 100 in accordance with some aspects. In some aspects, the device 100 may include application circuitry 102, baseband circuitry 104, Radio Frequency (RF) circuitry 106, front-end module (FEM) circuitry 108, one or more antennas 110, and power management circuitry (PMC) 112 coupled together at least as shown. The components of the illustrated device 100 may be included in a UE or a RAN node. In some aspects, the device 100 may include less elements (e.g., a RAN node may not utilize application circuitry 102, and instead include a processor/controller to process IP data received from an EPC). In some aspects, the device 100 may include additional elements such as, for example, memory/storage, display, camera, sensor, or input/output (I/O) interface. In other aspects, the components described below may be included in more than one device (e.g., said circuitries may be separately included in more than one device for Cloud-RAN (C-RAN) implementations).

The application circuitry 102 may include one or more application processors. For example, the application circuitry 102 may include circuitry such as, but not limited to, one or more single-core or multi-core processors. The processor(s) may include any combination of general-purpose processors and dedicated processors (e.g., graphics processors, application processors, etc.). The processors may be coupled with or may include memory/storage and may be configured to execute instructions stored in the memory/storage to enable various applications or operating systems to run on the device 100. In some aspects, processors of application circuitry 102 may process IP data packets received from an EPC.

The baseband circuitry 104 may include circuitry such as, but not limited to, one or more single-core or multi-core processors. The baseband circuitry 104 may include one or more baseband processors or control logic to process baseband signals received from a receive signal path of the RF circuitry 106 and to generate baseband signals for a transmit signal path of the RF circuitry 106. Baseband processing circuity 104 may interface with the application circuitry 102 for generation and processing of the baseband signals and for controlling operations of the RF circuitry 106. For example, in some aspects, the baseband circuitry 104 may include a third generation (3G) baseband processor 104A, a fourth generation (4G) baseband processor 104B, a fifth generation (5G) baseband processor 104C, or other baseband processor(s) 104D for other existing generations, generations in development or to be developed in the future (e.g., second generation (2G), sixth generation (6G), etc.). The baseband circuitry 104 (e.g., one or more of baseband processors 104A-D) may handle various radio control functions that enable communication with one or more radio networks via the RF circuitry 106. In other aspects, some or all of the functionality of baseband processors 104A-D may be included in modules stored in the memory 104G and executed via a Central Processing Unit (CPU) 104E. The radio control functions may include, but are not limited to, signal modulation/demodulation, encoding/decoding, radio frequency shifting, etc. In some aspects, modulation/demodulation circuitry of the baseband circuitry 104 may include Fast-Fourier Transform (FFT), precoding, or constellation mapping/demapping functionality. In some aspects, encoding/decoding circuitry of the baseband circuitry 104 may include convolution, tail-biting convolution, turbo, Viterbi, or Low Density Parity Check (LDPC) encoder/decoder functionality. Examples of modulation/demodulation and encoder/decoder functionality are not limited to these aspects and may include other suitable functionality in other aspects.

In some aspects, the baseband circuitry 104 may include one or more audio digital signal processor(s) (DSP) 104F. The audio DSP(s) 104F may include elements for compression/decompression and echo cancellation and may include other suitable processing elements in other aspects. Components of the baseband circuitry may be suitably combined in a single chip, a single chipset, or disposed on a same circuit board in some aspects. In some aspects, some or all of the constituent components of the baseband circuitry 104 and the application circuitry 102 may be implemented together such as, for example, on a system on a chip (SOC).

In some aspects, the baseband circuitry 104 may provide for communication compatible with one or more radio technologies. For example, in some aspects, the baseband circuitry 104 may support communication with an evolved universal terrestrial radio access network (EUTRAN) or other wireless metropolitan area networks (WMAN), a wireless local area network (WLAN), a wireless personal area network (WPAN). Aspects in which the baseband circuitry 104 is configured to support radio communications of more than one wireless protocol may be referred to as multi-mode baseband circuitry.

RF circuitry 106 may enable communication with wireless networks using modulated electromagnetic radiation through a non-solid medium. In various aspects, the RF circuitry 106 may include switches, filters, amplifiers, etc. to facilitate the communication with the wireless network. RF circuitry 106 may include a receive signal path which may include circuitry to down-convert RF signals received from the FEM circuitry 108 and provide baseband signals to the baseband circuitry 104. RF circuitry 106 may also include a transmit signal path which may include circuitry to up-convert baseband signals provided by the baseband circuitry 104 and provide RF output signals to the FEM circuitry 108 for transmission.

In some aspects, the receive signal path of the RF circuitry 106 may include mixer circuitry 106a, amplifier circuitry 106b and filter circuitry 106c. In some aspects, the transmit signal path of the RF circuitry 106 may include filter circuitry 106c and mixer circuitry 106a. RF circuitry 106 may also include synthesizer circuitry 106d for synthesizing a frequency for use by the mixer circuitry 106a of the receive signal path and the transmit signal path. In some aspects, the mixer circuitry 106a of the receive signal path may be configured to down-convert RF signals received from the FEM circuitry 108 based on the synthesized frequency provided by synthesizer circuitry 106d. The amplifier circuitry 106b may be configured to amplify the down-converted signals, and the filter circuitry 106c may be a low-pass filter (LPF) or a band-pass filter (BPF) configured to remove unwanted signals from the down-converted signals to generate output baseband signals. Output baseband signals may be provided to the baseband circuitry 104 for further processing. In some aspects, the output baseband signals may be zero-frequency baseband signals, although this is not a requirement. In some aspects, mixer circuitry 106a of the receive signal path may comprise passive mixers, although the scope of the aspects is not limited in this respect.

In some aspects, the mixer circuitry 106a of the transmit signal path may be configured to up-convert input baseband signals based on the synthesized frequency provided by the synthesizer circuitry 106d to generate RF output signals for the FEM circuitry 108. The baseband signals may be provided by the baseband circuitry 104 and may be filtered by filter circuitry 106c.

In some aspects, the mixer circuitry 106a of the receive signal path and the mixer circuitry 106a of the transmit signal path may include two or more mixers and may be arranged for quadrature downconversion and upconversion, respectively. In some aspects, the mixer circuitry 106a of the receive signal path and the mixer circuitry 106a of the transmit signal path may include two or more mixers and may be arranged for image rejection (e.g., Hartley image rejection). In some aspects, the mixer circuitry 106a of the receive signal path and the mixer circuitry 106a of the transmit signal path may be arranged for direct downconversion and direct upconversion, respectively. In some aspects, the mixer circuitry 106a of the receive signal path and the mixer circuitry 106a of the transmit signal path may be configured for super-heterodyne operation.

In some aspects, the output baseband signals and the input baseband signals may be analog baseband signals, although the scope of the aspects is not limited in this respect. In some alternate aspects, the output baseband signals and the input baseband signals may be digital baseband signals. In these alternate aspects, the RF circuitry 106 may include analog-to-digital converter (ADC) and digital-to-analog converter (DAC) circuitry, and the baseband circuitry 104 may include a digital baseband interface to communicate with the RF circuitry 106.

In some dual-mode aspects, a separate radio IC circuitry may be provided for processing signals for each spectrum, although the scope of the aspects is not limited in this respect.

In some aspects, the synthesizer circuitry 106d may be a fractional-N synthesizer or a fractional N/N+1 synthesizer, although the scope of the aspects is not limited in this respect as other types of frequency synthesizers may be suitable. For example, synthesizer circuitry 106d may be a delta-sigma synthesizer, a frequency multiplier, or a synthesizer comprising a phase-locked loop with a frequency divider.

The synthesizer circuitry 106d may be configured to synthesize an output frequency for use by the mixer circuitry 106a of the RF circuitry 106 based on a frequency input and a divider control input. In some aspects, the synthesizer circuitry 106d may be a fractional N/N+1 synthesizer.

In some aspects, frequency input may be provided by a voltage controlled oscillator (VCO), although that is not a requirement. Divider control input may be provided by either the baseband circuitry 104 or the applications processor 102 depending on the desired output frequency. In some aspects, a divider control input (e.g., N) may be determined from a look-up table based on a channel indicated by the applications processor 102.

Synthesizer circuitry 106d of the RF circuitry 106 may include a divider, a delay-locked loop (DLL), a multiplexer and a phase accumulator. In some aspects, the divider may be a dual modulus divider (DMD) and the phase accumulator may be a digital phase accumulator (DPA). In some aspects, the DMD may be configured to divide the input signal by either N or N+1 (e.g., based on a carry out) to provide a fractional division ratio. In some aspects, the DLL may include a set of cascaded, tunable, delay elements, a phase detector, a charge pump and a D-type flip-flop. In these aspects, the delay elements may be configured to break a VCO period up into N_{d} equal packets of phase, where N_{d} is the number of delay elements in the delay line. In this way, the DLL provides negative feedback to help ensure that the total delay through the delay line is one VCO cycle.

In some aspects, synthesizer circuitry 106d may be configured to generate a carrier frequency as the output frequency, while in other aspects, the output frequency may be a multiple of the carrier frequency (e.g., twice the carrier frequency, four times the carrier frequency) and used in conjunction with quadrature generator and divider circuitry to generate multiple signals at the carrier frequency with multiple different phases with respect to each other. In some aspects, the output frequency may be a LO frequency (f_{LO}). In some aspects, the RF circuitry 106 may include an IQ/polar converter.

FEM circuitry 108 may include a receive signal path which may include circuitry configured to operate on RF signals received from one or more antennas 110, amplify the received signals, and provide the amplified versions of the received signals to the RF circuitry 106 for further processing. FEM circuitry 108 may also include a transmit signal path which may include circuitry configured to amplify signals for transmission provided by the RF circuitry 106 for transmission by one or more of the one or more antennas 110. In various aspects, the amplification through the transmit or receive signal paths may be done solely in the RF circuitry 106, solely in the FEM 108, or in both the RF circuitry 106 and the FEM 108.

In some aspects, the FEM circuitry 108 may include a TX/RX switch to switch between transmit mode and receive mode operation. The FEM circuitry may include a receive signal path and a transmit signal path. The receive signal path of the FEM circuitry may include an LNA to amplify received RF signals and provide the amplified received RF signals as an output (e.g., to the RF circuitry 106). The transmit signal path of the FEM circuitry 108 may include a power amplifier (PA) to amplify input RF signals (e.g., provided by RF circuitry 106), and one or more filters to generate RF signals for subsequent transmission (e.g., by one or more of the one or more antennas 110).

FIG. 1B shows the PMC 112 coupled only with the baseband circuitry 104. However, in other aspects, the PMC 112 may be additionally or alternatively coupled with, and perform similar power management operations for, other components such as, but not limited to, application circuitry 102, RF circuitry 106, or FEM 108.

Processors of the application circuitry 102 and processors of the baseband circuitry 104 may be used to execute elements of one or more instances of a protocol stack. For example, processors of the baseband circuitry 104, alone or in combination, may be used to execute Layer 3, Layer 2, or Layer 1 functionality, while processors of the application circuitry 104 may utilize data (e.g., packet data) received from these layers and further execute Layer 4 functionality (e.g., transmission communication protocol (TCP) and user datagram protocol (UDP) layers). As referred to herein, Layer 3 may comprise a radio resource control (RRC) layer, described in further detail below. As referred to herein, Layer 2 may comprise a medium access control (MAC) layer, a radio link control (RLC) layer, and a packet data convergence protocol (PDCP) layer, described in further detail below. As referred to herein, Layer 1 may comprise a physical (PHY) layer of a UE/RAN node.

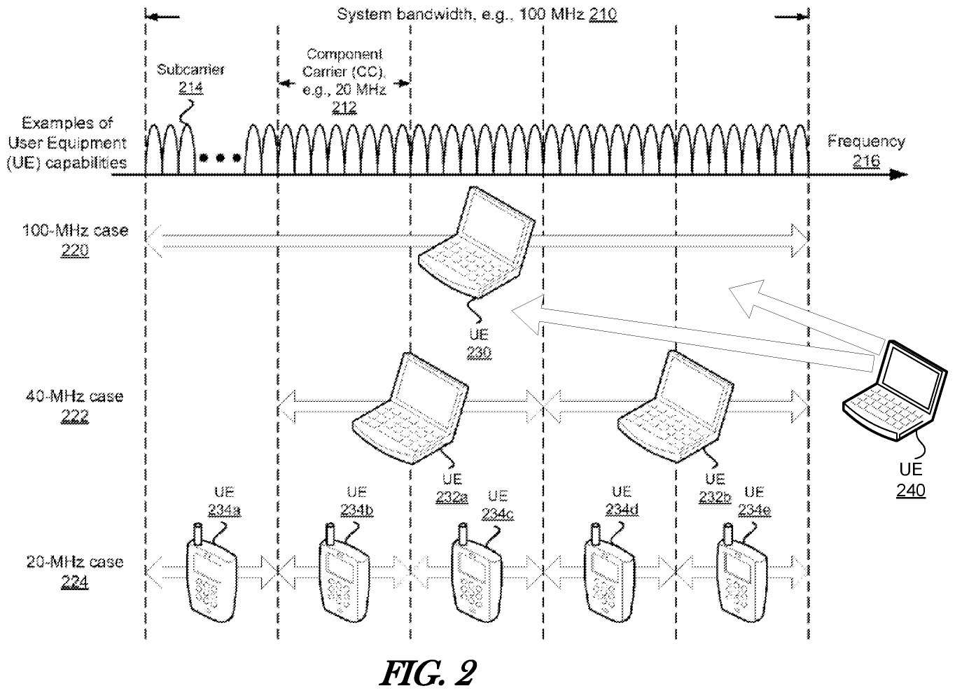

In carrier aggregation (CA), component carriers (CCs) for a UMTS Terrestrial Radio Access Network can be combined together to form a larger bandwidth for the UE, as illustrated in FIG. 2. For example, the UMTS may have a system bandwidth 210 of 100 MHz in a frequency spectrum 216 with each CC 212 having a 20 MHz bandwidth. Each CC may comprise a plurality of subcarriers 214. Some UEs 230 may use the entire 100 MHz system bandwidth by aggregating five 20 MHz CCs together to achieve a 100 MHz UE bandwidth 220. In another aspect, two UEs 232a and 232b each with a 40 MHz bandwidth capability may each use two 20 MHz CCs together to achieve a 40 MHz UE bandwidth 222 for each UE. In another aspect, each UE 234a-e may use a single 20 MHz CC to achieve a 20 MHz UE bandwidth 224. The CCs at a base station may be aggregated for some UEs while other UEs may use a single CC during the same interval. For example, one UE with a 40 MHz bandwidth may be configured while three UEs that each use a single 20 MHz CC are employed in a 100 MHz bandwidth system (not shown). Carrier aggregation allows the bandwidth for a UE to be adjusted and adapted based on the system limitations, the UEs capabilities and bandwidth requirements, the bandwidth available to the system and/or loading on the system.

In a related aspect, UE 240 may be configured to use two separate CCs that are not contiguous to achieve a total bandwidth of 40 MHz made up of the two separate 20-MHz CCs. As described in greater detail below, the FEM circuitry of UE 240 may accomplish the non-contiguous CA operation using distinct filtering and amplification subcircuitry corresponding to each CC. The FEM circuitry may also support contiguous CA operation with wider-bandwidth filtering and amplification. As will be described in greater detail below, various challenges of supporting non-CA, contiguous CA, and non-contiguous CA operation in the same FEM circuitry are addressed according to aspects of the present subject matter.

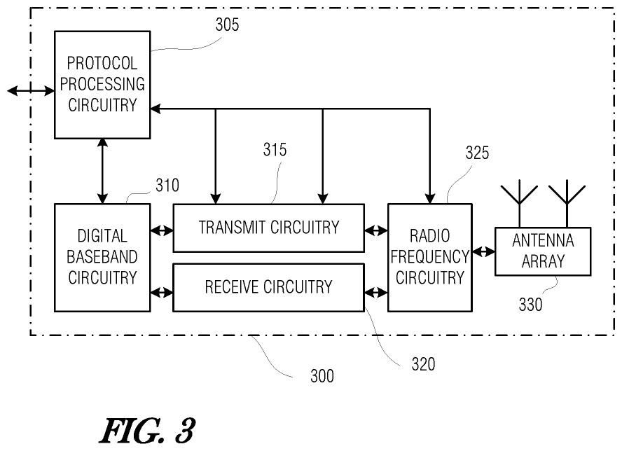

FIG. 3 illustrates communication circuitry 300 according to some aspects. In the aspect depicted, communication circuitry 300 is grouped according to function. Components as shown in FIG. 3 are shown here for illustrative purposes and may include other components not shown here in FIG. 3.

Communication circuitry 300 may include protocol processing circuitry 305, which may implement one or more of medium access control (MAC), radio link control (RLC), packet data convergence protocol (PDCP), radio resource control (RRC) and non-access stratum (NAS) functions. Protocol processing circuitry 305 may include one or more processing cores (not shown) to execute instructions and one or more memory structures (not shown) to store program and data information.

Communication circuitry 300 may further include digital baseband circuitry 310, which may implement physical layer (PHY) functions including one or more of hybrid automatic repeat request (HARQ) functions, scrambling and/or descrambling, coding and/or decoding, layer mapping and/or de-mapping, modulation symbol mapping, received symbol and/or bit metric determination, multi-antenna port pre-coding and/or decoding which may include one or more of space-time, space-frequency or spatial coding, reference signal generation and/or detection, preamble sequence generation and/or decoding, synchronization sequence generation and/or detection, control channel signal blind decoding, and other related functions.

Communication circuitry 300 may further include transmit circuitry 315, receive circuitry 320 and/or antenna array circuitry 330.

Communication circuitry 300 may further include radio frequency (RF) circuitry 325. In an aspect of the disclosure, RF circuitry 325 may include multiple parallel RF chains for one or more of transmit or receive functions, each connected to one or more antennas of the antenna array 330.

In an aspect of the disclosure, protocol processing circuitry 305 may include one or more instances of control circuitry (not shown) to provide control functions for one or more of digital baseband circuitry 310, transmit circuitry 315, receive circuitry 320, and/or radio frequency circuitry 325.

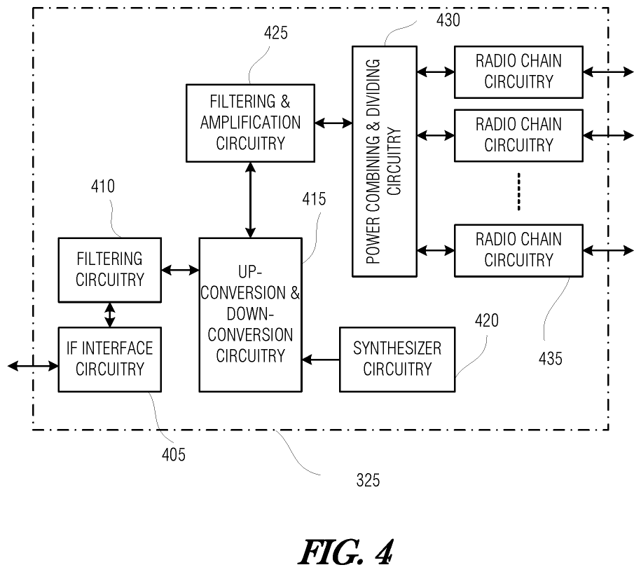

FIG. 4 illustrates RF circuitry 325 in greater detail according to some aspects. RF circuitry 325 may include one or more of each of intermediate frequency (IF) interface circuitry 405, filtering circuitry 410, upconversion and downconversion circuitry 415, synthesizer circuitry 420, filtering and amplification circuitry 425, power combining and dividing circuitry 430, and radio chain circuitry 435.

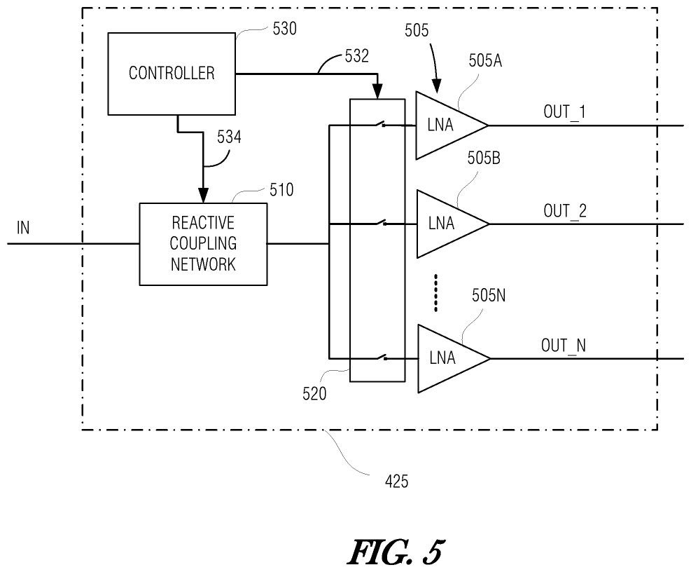

FIG. 5 is a block-level schematic diagram illustrating a portion of filtering and amplification circuitry 425 according to some aspects. In this aspect, filtering and amplification circuitry 425 includes a split-LNA arrangement, in which there are two or more distinct LNA circuits that share a common input, and produce respective distinct outputs that may be fed to distinct paths of mixer circuitry of up-conversion and down-conversion circuitry 415 (FIG. 4). Each distinct LNA and downstream path may be specifically tuned or optimized for a respective CC, for example. As depicted in FIG. 5, input IN is selectively fed to LNA 505A, LNA 505B, or LNA 505N, or to some combination of two or more LNAs 505, which respectively produce outputs OUT_1, OUT_2, and OUT_N to be separately processed downstream.

Reactive coupling network 510 facilitates the coupling of input IN to LNAs 505A, 505B, and 505N. Optionally, split-LNA selector 520 facilitates the selection of one, two, or more of LNAs 505. Controller 530 provides a LNA selection control signal 532 to split-LNA selector 520 to enable one, two, or more of the LNAs. In another aspect, selector switch 520 is omitted; instead, each of the LNAs is selectively enabled or disabled with a different mechanism. For instance, bias currents in the LNA circuitry may be turned on or off. Notably, turning on or off of a given LNA using this approach still affects the gate capacitance of the respective input transistors, which is often a major component of the input capacitance.

In one aspect, controller 530 produces coupling adjustment signal 534 to reactive coupling network 510 in order to control the input impedance as seen by input signal IN. Coupling adjustment signal 534 may be based on the split-LNA selection. For instance, the input impedance may be set to correspond to the quantity of LNAs 505 that are enabled for split-LNA operation. In a related aspect, coupling adjustment signal 534 may be further based on the particular frequencies of the CCs used for CA operation. For instance, the input impedance may be optimized to match the input characteristics at the carrier frequencies currently in use.

According to some aspects, coupling network 510 is selectively switched in and, in some aspects, varied, in order to address the challenge of mismatched return losses attributable to the different LNAs. For example, the input signal IN may be provided by a buffer circuit (not shown) that is designed to optimally drive a particular input impedance. As a consequence of switching the different LNAs in and out as part of the CA operation, the input impedance as seen by the buffer circuit may be variable and often not optimally matched with the buffer circuit's output. A mismatched arrangement results in greater return losses and hence reduced performance of LNAs 505. Advantageously, the addition, of reactive coupling network 510 stabilizes the input impedance as LNAs 505 are switched in and out. Additionally, the adjustment of the impedance of reactive coupling network 510 allows more accurate matching of the input impedance to LNAs 505 with the input signal IN as different quantities of LNAs 505 are activated over time, and as the CC frequencies are varied over time for intra-band CA operation.

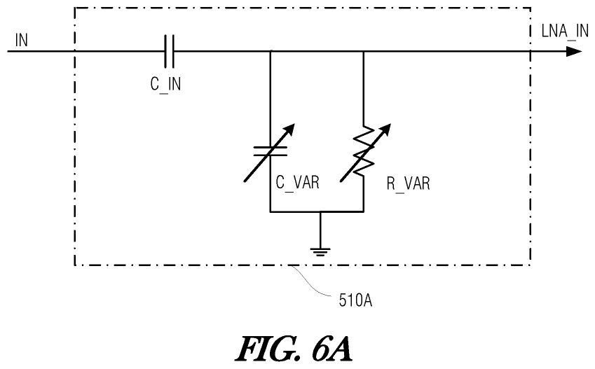

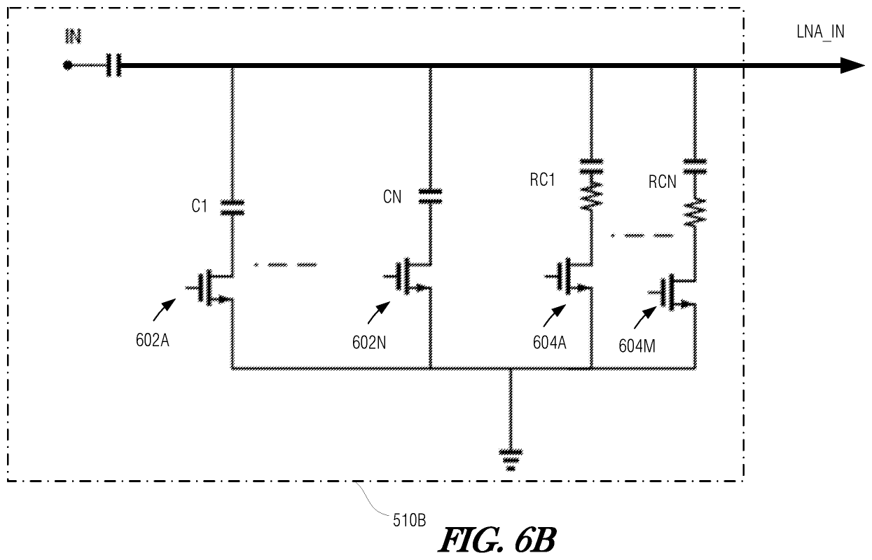

In one sense, reactive coupling network 510 facilitates variation of a time constant associated with the reactance. FIG. 6A is a simplified schematic diagram illustrating reactive coupling network 510A according to one aspect. As depicted, reactive coupling network 510A includes coupling capacitor C_IN placed in series with input signal IN, and variable capacitor C_VAR, and variable resistor R_VAR placed in a shunt configuration with LNA input LNA_IN.

In a related aspect, the variability of capacitor C_VAR and resistor R_VAR is digitally controllable. In a basic implementation, capacitor C_VAR and resistor R_VAR are each variable in a binary sense of being either switchably included in, or excluded from, reactive coupling network 510. In various more advanced implementations, the value of capacitor C_VAR, resistor R_VAR, or both, is/are selectively variable. For example, a m-bit control signal may be used to regulate the value of capacitor C_VAR or resistor R_VAR, or to select from various paired-value combinations of capacitor C_VAR and resistor R_VAR, where m may be 2, 3, 4, 5, or more bits.

As one aspect, capacitor C_VAR may be implemented as a switchable bank of fixed capacitor values that may be switchably combined in series or parallel in various quantities. Similarly, resistor R_VAR may be implemented as a switchable bank of resistance elements that may be switchably combined in series or parallel in various quantities. In another aspect, electrically-variable capacitor and resistor elements may be formed using conventional fabrication techniques.

FIG. 6B is a simplified schematic diagram illustrating a variation of a reactive coupling network according to another example. As depicted, reactive coupling network 510B includes a bank of switchable fixed-value capacitors C1-CN, which are switchable via transistors 602A-602N. Additionally, a bank of switchable resistor-capacitor subcircuits RC1-RCN, switchable via transistors 604A-604M, may be provided.

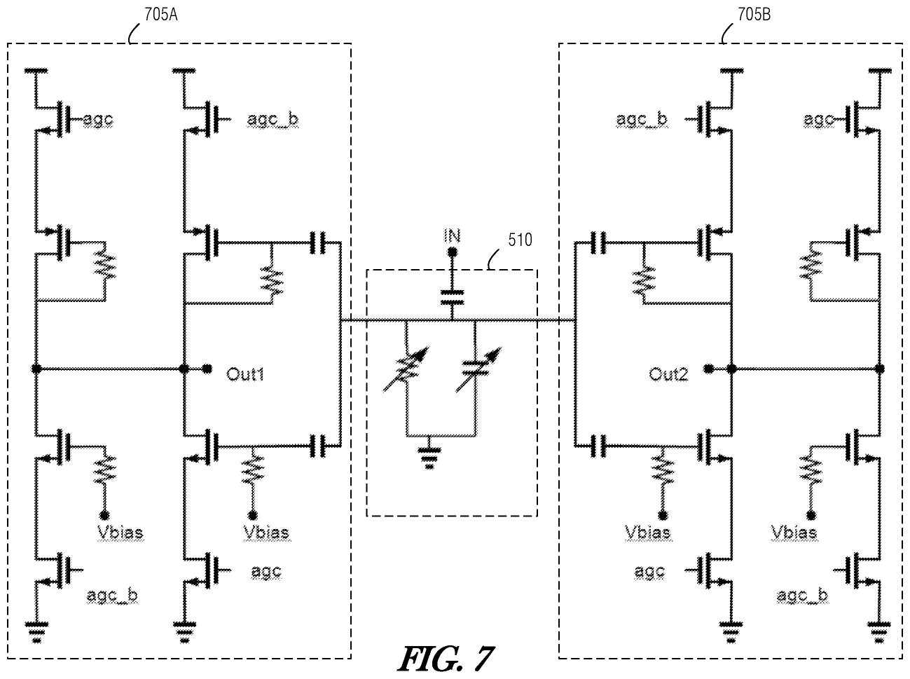

FIG. 7 is a transistor-level schematic diagram illustrating a switched-LNA arrangement in greater detail according to an aspect. The switched-LNA arrangement of FIG. 7 incorporates complementary metal-oxide-semiconductor (CMOS) technology. A first LNA 705A and a second LNA 705B are each fed an input signal IN via reactive coupling network 510. The circuit arrangement as illustrated includes input nodes for automatic gain control (AGC), agc and agc_b, as well as nodes for establishing a bias current in the LNAs, Vbias. First LNA 705A produces output signal Out 1, whereas second LNA 705B produces output signal Out2, as shown. The switched-LNA arrangement of FIG. 7 can operate in the frequency range of 600 MHz to 2.7 GHz according to some aspects.

A related aspect of the present subject matter is directed to a LNA circuit topology that facilitates high-frequency and wide-bandwidth operation. In an aspect, a LNA circuit may facilitate operation in the 5-6 GHz band, with a bandwidth on the order of 1 GHz, though it will be understood that similar principles may be applicable in other bands with greater or smaller bandwidths.

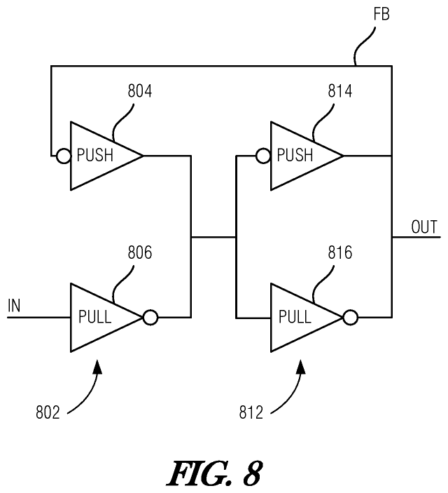

FIG. 8 is a block-level schematic diagram illustrating some features of a LNA according to an aspect. As depicted, the LNA of FIG. 8 includes a first stage 802 of push-pull amplifier elements 804 and 806, and a second stage 812 of push-pull amplifier elements 814 and 816. Amplifier elements 804 and 814 are arranged in a push configuration, and amplifier elements 806 and 816 are arranged in a pull configuration. Input signal IN is fed to only pull amplifier element 806. Output signal OUT is driven by push amplifier element 814 and pull amplifier element 816 working in concert. Feedback path FB couples output signal OUT to the input of push amplifier element 804.

Advantageously, input signal IN sees only the impedance of pull amplifier element 806, and any parasitic capacitance associated with its input. The input to push amplifier element 804 is driven by feedback FB from the output of second stage 812, which offloads input and parasitic capacitance of push amplifier element 804 from input signal IN. In addition, the two-stage arrangement provides increased amplification gain over a single-stage arrangement.

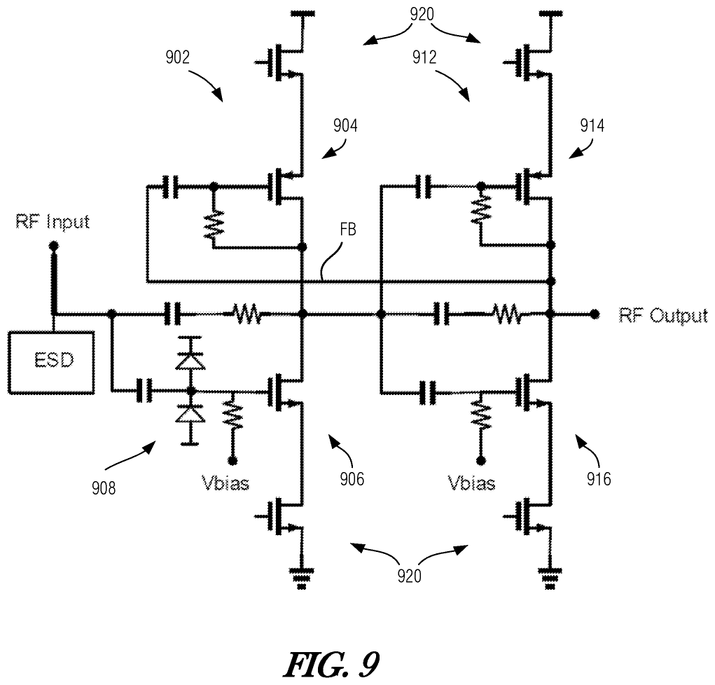

FIG. 9 is a transistor-level schematic diagram illustrating an aspect of a LNA circuit incorporating CMOS technology. As depicted, the LNA of FIG. 9 includes a first stage 902 of push-pull transistors, including p-channel field-effect transistor (FET) 904 and n-channel FET 906. A second stage 912 of push-pull transistors includes p-channel FET 914 and n-channel FET 916. Input signal RF Input is fed to the gate of first-stage pull transistor 906. Output signal RF Output is driven by second-stage push transistor 914 and second-stage pull transistor 916 working in concert. Feedback path FB couples output signal RF Output to the gate of p-channel FET 904. Gain-control transistors 920 may be provided with automatic gain control (AGC) signaling (not shown). In some aspects, the LNA of FIG. 9 can operate in the frequency range of 5 GHz to 6 GHz.

Also shown in the schematic diagram of FIG. 9 are electrostatic discharge (ESD) protection subcircuit labeled ESD, and additional transient protection diodes indicated at 908. The ESD and transient protection 908 subcircuits each introduce parasitic capacitance. In addition, there is parasitic capacitance at the gate of n-channel FET 906 that is also seen by input signal RF Input. These parasitic capacitances tend to degrade high-frequency performance of the LNA. Advantageously, by providing the input signal to p-channel FET 904 from the RF Output node using feedback FB rather than from the RF Input signal, ESD and additional transient protection for p-channel FET 904 are not needed. Also, the parasitic capacitance of the gate of p-channel FET 904 is not presented to the RF Input, thus facilitating high-frequency operation.

Another aspect of the present subject matter is directed to a multi-band configuration for a LNA. A multi-band LNA according to this aspect is dynamically reconfigurable for operation in a relatively lower-frequency band, and in a relatively higher-frequency band. As an example, the relatively lower frequency band may be in the 1.8-2.7 GHz frequency range, whereas the relatively higher frequency band may be in the 5-6 GHz range. It will be understood that the principles facilitating the multi-band LNA operation are applicable in other frequency ranges with suitable circuitry adaptation.

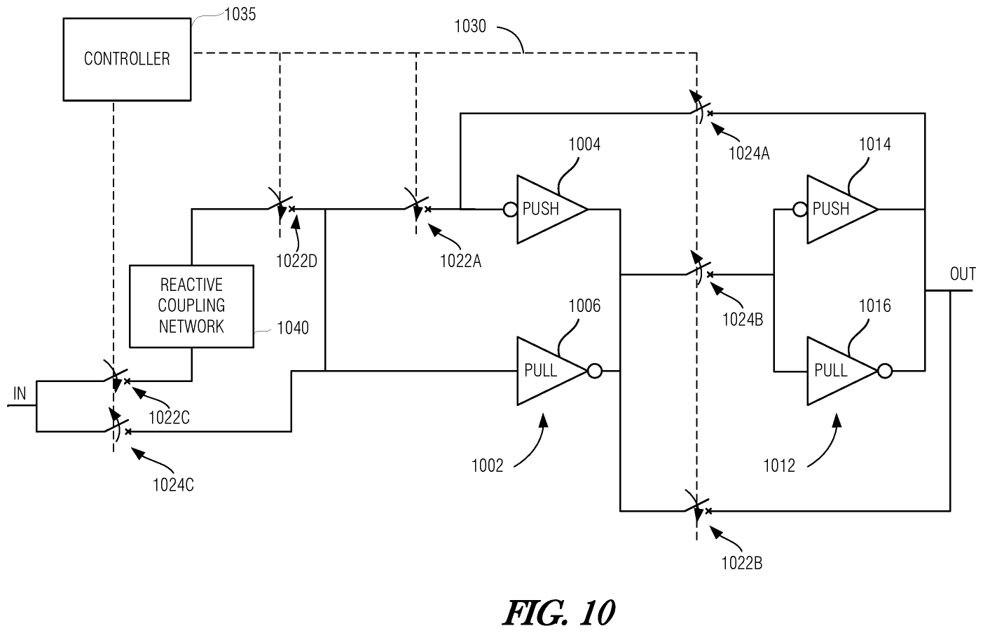

FIG. 10 is a block-level schematic diagram illustrating an aspect LNA arrangement for dynamically-reconfigurable multi-band operation. As depicted, the LNA of FIG. 10 includes a first stage 1002 of push-pull amplifier elements 1004 and 1006, and a switched second stage 1012 of push-pull amplifier elements 1014 and 1016. Amplifier elements 1004 and 1014 are arranged in a push configuration, and amplifier elements 1006 and 1016 are arranged in a pull configuration.

Switched second stage 1012 may be either included, or bypassed, from the LNA circuit in accordance with the multi-band operation. As an example, for operation in the lower-frequency band, second stage 1012 may be bypassed; whereas for operation in the higher-frequency band, second stage 1012 may be included. Switches 1022A, 1022B, 1024A and 1024B are arranged to selectively add and remove second stage 1012 from the LNA circuitry. In bypass mode, switches 1022A and 1022B are closed, while switches 1024A and 1024B are opened. In two-stage mode, the switches are placed in their opposite states with switches 1022A and 1022B open and switches 1024A and 1024B closed. Switch control signal 1030 may be supplied from controller 1035 to each of the switches to control their respective states, with switches 1022A and 1022B taking the opposite state from switches 1024A and 1024B for a given switch control signal 1030.

In the bypass mode, switch 1022A is closed, such that input signal IN is fed to amplifier elements 1004 and 1006. Likewise, switch 1022B is closed such that the output of amplifier elements 1004 and 1006 constitutes output signal OUT. In the two-stage mode, switch 1022A is open, such that input signal IN is not supplied to amplifier element 1004. Instead, switch 1024A is closed, which feeds the output of amplifier elements 1014 and 1016 to the input of amplifier element 1004 in similar fashion to the aspect described above with reference to FIG. 8. Also in the two-stage mode, switch 1024B is closed to feed the output of amplifier elements 1004 and 1006 to the inputs of second-stage amplifier elements 1014 and 1016.

In a related aspect, reactive coupling network 1040 is provided to support a switched-LNA arrangement to operate in similar fashion as described above with reference to FIG. 5. In some aspects, coupling network 1040 is suitable for use while the LNA is in the bypass mode. Accordingly, switches 1022C and 1022D are operated together to insert or remove reactive coupling network 1040 to or from the input path to first stage 1002. Additionally, switch 1024C is operated in the alternative state to switches 1022C and 1022D to provide a direct coupling for input signal IN to first stage 1002.

Advantageously, the input impedance, linearity, and gain of the dynamically-reconfigurable LNA of FIG. 10 are adjusted by the switching in and out of the second stage 1012 to support operation in the respective higher-frequency and lower-frequency bands.

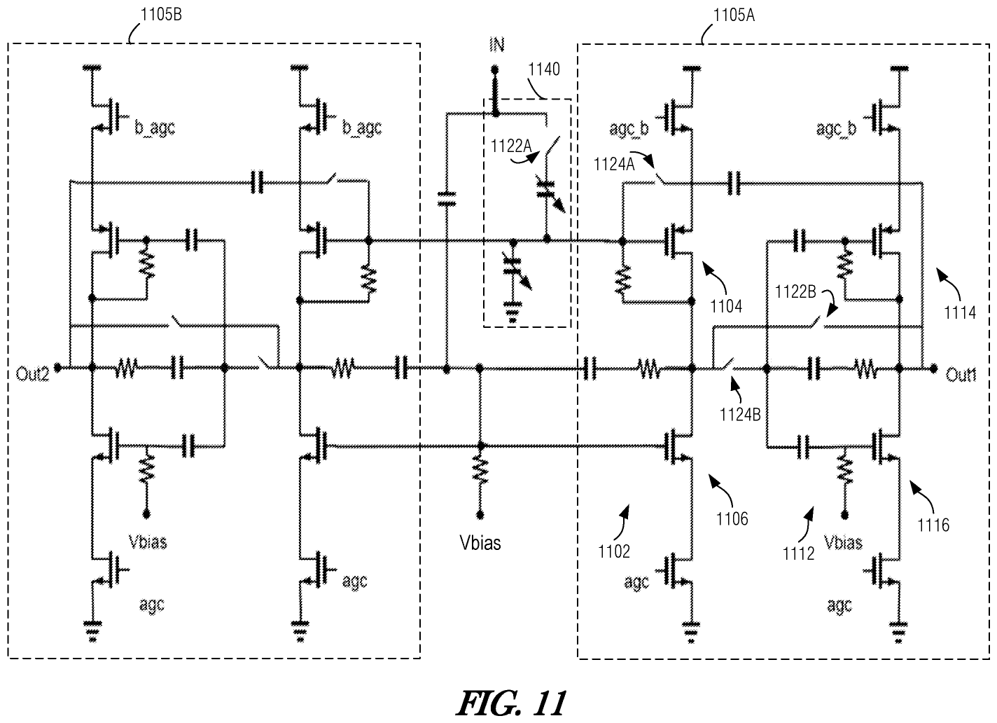

FIG. 11 is a transistor-level schematic diagram illustrating an aspect of a switched-LNA arrangement that features dynamically-configurable multi-band operation. The switched-LNA arrangement of FIG. 11 incorporates CMOS technology. A first LNA 1105A and a second LNA 1105B are each fed an input signal IN via reactive coupling network 1140. The circuit arrangement as illustrated includes input nodes for automatic gain control (AGC), agc and agc_b, and b_agc, as well as nodes for establishing a bias current in the LNAs, Vbias. First LNA 1105A produces output signal Out1, whereas second LNA 1105B produces output signal Out2, as shown. In some aspects, the LNA of FIG. 11 can operate in the frequency range of 1.8 GHz to 3.6 GHz.

Details of first LNA 1105 are described as follows. Second LNA 1105B (and additional LNAs, if provided) would have similar arrangements. First LNA 1105A includes a first stage 1102 of push-pull transistors 1104 and 1106, and a switched second stage 1112 of push-pull transistors 1114 and 1116. Transistors 1104 and 1114 are p-channel devices arranged in a push configuration, and transistors 1106 and 1116 are n-channel devices arranged in a pull configuration.

Switched second stage 1112 may be either included, or bypassed, from first LNA 1105A in accordance with the multi-band operation. As an example, for operation in the lower-frequency band, second stage 1112 may be bypassed; whereas for operation in the higher-frequency band, second stage 1112 may be included. Switches 1122A, 1122B, 1124A and 1124B are arranged to selectively add and remove second stage 1112 from the LNA circuitry. In bypass mode, switches 1122A and 1122B are closed, while switches 1124A and 1124B are opened. In two-stage mode, the switches are placed in their opposite states with switches 1122A and 1122B open and switches 1124A and 1124B closed.

In the bypass mode, switch 1122A is closed, such that input signal IN is fed to transistors 1104 and 1106. Likewise, switch 1122B is closed such that the output of transistors 1104 and 1106 constitutes output signal OUT1. In the two-stage mode, switch 1122A is open, such that input signal IN is not supplied to p-channel transistor 1104. Instead, switch 1124A is closed, which feeds the output of transistors 1114 and 1116 to the gate of transistor 1104. Also in the two-stage mode, switch 1124B is closed to couple the output of transistors 1104 and 1106 to the gates of second-stage transistors 1114 and 1116.

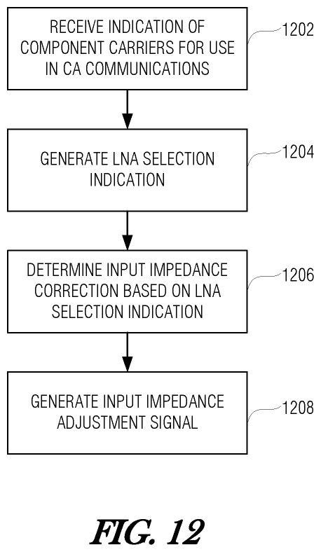

FIG. 12 is a process flow diagram illustrating an example set of operations to be carried out by controller 530 of the switched-LNA arrangement of FIG. 5. At 1202, controller 530 receives an indication of the CCs to be received as part of intra-band CA communications. Based on the identified CCs, at 1204 controller 530 selects which LNAs are to be used, and generates a selection indication of LNAs to be enabled. As discussed above, enablement of different quantities of LNAs affects the input impedance to the greater LNA circuitry. At 1206, controller 530 determines the input impedance correction to be made based on the LNA selection. The impedance correction may be determined using a lookup table of predefined values corresponding to the various possible LNA combinations, for instance. In another example, the impedance correction may be formulaically determined. At 1208, controller 530 generates an input impedance adjustment signal to be supplied to reactive coupling network 510. As discussed above, the input impedance adjustment signal may include a binary indication, or a multi-bit value for an adjustable resistor, capacitor, or both.

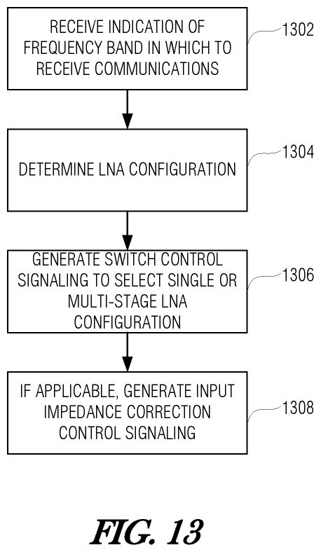

FIG. 13 is a process flow diagram illustrating an example set of operations to be carried out by controller 1035 of the multi-band LNA arrangement of FIG. 10. At 1302, controller 1035 receives an indication (e.g., from a baseband processor) of the frequency band in which the RF circuitry is to receive communications. At 1304, controller 1035 determines the LNA configuration to be used from among high-band or low-band configurations. At 1306, controller 1035 generates switch control signaling to either activate the second amplification stage, or bypass the second amplification stage, accordingly. At 1308, controller generates input impedance control signaling, such as the input impedance adjustment signal described above, if the selected LNA configuration supports variable input capacitance adjustment.

It should be noted that controllers 530 and 1035 may be the same controller in an example LNA circuit. Either controller may be implemented in hardware as an instruction-based controller that executes firmware instructions, or as a state machine implemented using logic circuitry. The controller circuitry may include data storage circuitry such as read-only memory (ROM), random-access memory (RAM), non-volatile memory, or the like, as well as suitable interface circuitry for accessing the data storage circuitry, and facilitating input and output of data or control signaling.

Additional Notes and Examples:

Example 1 is a radio-frequency (RF) amplifier circuit facilitating carrier-aggregation (CA) operation in a wireless communication network, the RF amplifier circuit comprising: an input node; a first amplifier subcircuit electrically coupled to the input node, and a second amplifier subcircuit electrically coupled to the input node, the first amplifier subcircuit to amplify a first RF carrier to produce a first output, and the second amplifier subcircuit to amplify a second RF carrier to produce a second output, wherein the first RF carrier and the second RF carrier are to be received simultaneously or concurrently; an amplifier subcircuit selector to selectively enable operation of the first amplifier subcircuit, the second amplifier subcircuit, or the first and the second amplifier subcircuits together, in response to a selection indication. In some cases, various enablement configurations of the first and the second amplifier subcircuits are associated with input impedance variation at the input node. A reactive coupling network is arranged to selectively adjust the input impedance at the input node in response to the selection indication to reduce the input impedance variation.

In Example 2, the subject matter of Example 1 includes, wherein the first RF carrier and the second RF carrier are among a defined band of frequencies within the wireless communication network.

In Example 3, the subject matter of Examples 1-2 includes, wherein the first amplifier subcircuit and the second amplifier subcircuit are each a low-noise amplifier (LNA).

In Example 4, the subject matter of Examples 1-3 includes, wherein the reactive coupling network includes a control signal input to receive an adjustment signal corresponding to a desired input impedance, wherein the desired input impedance is based on the selection indication.

In Example 5, the subject matter of Example 4 includes, a controller subcircuit to produce: a selection control signal that includes the selection indication; and the adjustment signal.

In Example 6, the subject matter of Examples 1-5 includes, wherein the reactive coupling network includes a control signal input to receive an adjustment signal corresponding to a quantity of amplifier subcircuits that are to be selectively enabled.

In Example 7, the subject matter of Example 6 includes, wherein the adjustment signal corresponds further to a particular set of frequencies of the first RF carrier and the second RF carrier.

In Example 8, the subject matter of Examples 1-7 includes, wherein the input node is coupled to an input source having a source impedance, and wherein the input impedance variation causes variation in return loss as experienced by the input source; and wherein the reactive coupling network is to reduce the return loss by matching input impedance to the source impedance.

In Example 9, the subject matter of Examples 1-8 includes, wherein the first RF carrier is a first component carrier having a first plurality of subcarriers, and the second RF carrier is a component carrier having a second plurality of subcarriers.

In Example 10, the subject matter of Examples 1-9 includes, wherein first amplifier subcircuit and the second amplifier subcircuit are constructed to operate in a frequency range selected from among 600 MHz-2.7 GHz, 1.8 GHz to 3.6 GHz, or 5 GHz to 6 GHz.

In Example 11, the subject matter of Examples 1-10 includes, wherein first amplifier subcircuit and the second amplifier subcircuit include complementary metal-oxide-semiconductor (CMOS) transistors.

In Example 12, the subject matter of Examples 1-11 includes, wherein the reactive coupling network includes a variable capacitance.

In Example 13, the subject matter of Examples 1-12 includes, wherein the reactive coupling network is configured to produce a variable time constant.

In Example 14, the subject matter of Examples 1-13 includes, wherein the reactive coupling network includes a variable resistor-capacitor combination in a shunt configuration coupled to the input node.

In Example 15, the subject matter of Examples 12-14 includes, wherein the variable resistor-capacitor combination includes a variable resistor.

In Example 16, the subject matter of Examples 12-15 includes, wherein the variable resistor-capacitor combination includes a variable capacitor.

Example 17 is a wireless communication device comprising: RF circuitry that includes, a plurality of RF chains; a baseband circuitry; and the RF amplifier circuit according to any one of Examples 1-13.

In Example 18, the subject matter of Example 17 includes, an antenna array.

In Example 19, the subject matter of Examples 17-18 includes, application circuitry configured to carry out user equipment (UE) functionality in accordance with the wireless communication network.

In Example 20, the subject matter of Examples 17-19 includes, application circuitry configured to carry out base station functionality in accordance with the wireless communication network.

Example 21 is a radio-frequency (RF) amplifier circuit facilitating carrier-aggregation (CA) operation in a wireless communication network, the RF amplifier circuit comprising: input means; a first amplification means electrically coupled to the input means, and a second amplification means electrically coupled to the input means, the first amplification means to amplify a first RF carrier to produce a first output, and the second amplification means to amplify a second RF carrier to produce a second output, wherein the first RF carrier and the second RF carrier are to be received simultaneously; selection means to selectively enable operation of the first amplification mans, the second amplification means, or the first and the second amplification means together, in response to a selection indication; and reactive coupling means arranged to selectively adjust input impedance at the input means.

In Example 22, the subject matter of Example 21 includes, wherein the first RF carrier and the second RF carrier are among a defined band of frequencies within the wireless communication network.

In Example 23, the subject matter of Examples 21-22 includes, wherein the reactive coupling means includes a control signal input to receive an adjustment signal corresponding to a desired input impedance, wherein the desired input impedance is based on the selection indication.

In Example 24, the subject matter of Example 23 includes, control means to produce: a selection control signal that includes the selection indication; and the adjustment signal.

In Example 25, the subject matter of Examples 21-24 includes, wherein the reactive coupling means includes a control signal input to receive an adjustment signal corresponding to a quantity of amplification means that are to be selectively enabled.

In Example 26, the subject matter of Example 25 includes, wherein the adjustment signal corresponds further to a particular set of frequencies of the first RF carrier and the second RF carrier.

In Example 27, the subject matter of Examples 21-26 includes, wherein the input means is coupled to an input source having a source impedance, and wherein the input impedance variation causes variation in return loss as experienced by the input source; and wherein the reactive coupling means are to reduce the return loss by matching input impedance to the source impedance.

In Example 28, the subject matter of Examples 21-27 includes, wherein the first RF carrier is a first component carrier having a first plurality of subcarriers, and the second RF carrier is a component carrier having a second plurality of subcarriers.

In Example 29, the subject matter of Examples 21-28 includes, wherein the reactive coupling means include a variable capacitance.

In Example 30, the subject matter of Examples 21-29 includes, wherein the reactive coupling means are configured to produce a variable time constant.

In Example 31, the subject matter of Examples 21-30 includes, wherein the reactive coupling means include a variable resistor-capacitor combination in a shunt configuration coupled to the input means.

Example 32 is a method for operating a radio-frequency (RF) amplifier circuit facilitating carrier-aggregation (CA) operation in a wireless communication network, the method comprising: receiving, by a controller circuit, an indication of carriers for use in the CA operation; generating, by the controller circuit, an amplifier subcircuit selection indication indicating amplifier subcircuits to be selectively enabled from among at least a first amplifier subcircuit, and a second amplifier subcircuit, the amplifier subcircuit selection indication being based on the indication of carriers; determining, by the controller circuit, an input impedance correction for a common input node of the first amplifier subcircuit and the second amplifier subcircuit, based on the amplifier subcircuits to be selectively enabled; and generating, by the controller circuit, an input impedance adjustment signal representing electrical operations to be performed to effect the input impedance correction.

In Example 33, the subject matter of Example 32 includes, wherein the electrical operations include variation of capacitance of the common input node.

Example 34 is at least one machine-readable medium comprising instructions that, when executed by a controller circuit of a radio-frequency (RF) amplifier facilitating carrier-aggregation (CA) operation in a wireless communication network, causes the RF amplifier to: receive an indication of carriers for use in the CA operation; generate an amplifier subcircuit selection indication indicating amplifier subcircuits to be selectively enabled from among at least a first amplifier subcircuit, and a second amplifier subcircuit, the amplifier subcircuit selection indication being based on the indication of carriers;

determine an input impedance correction for a common input node of the first amplifier subcircuit and the second amplifier subcircuit, based on the amplifier subcircuits to be selectively enabled; and generate an input impedance adjustment signal representing electrical operations to be performed to effect the input impedance correction.

In Example 35, the subject matter of Example 34 includes, wherein the electrical operations include variation of capacitance of the common input node.

Example 36 is a radio-frequency (RF) amplifier circuit comprising: a signal input node; a first push-pull amplification stage including a first push amplifier element and a first pull amplifier element, the first pull amplifier element having a first input node being coupled to the signal input node and the first push amplifier element having a second input node that is not coupled to the signal input node, wherein the first push amplifier element and the first pull amplifier element are coupled at a common output node; and a second push-pull amplification stage including a second push amplifier element and a second pull amplifier element, the second push-pull amplification stage including a common inter-stage input node that is coupled to the common output node, and a signal output node that is coupled to the second input node of the first push amplifier element via a feedback path.

In Example 37, the subject matter of Example 36 includes, wherein the first and the second push amplifier elements are p-channel field effect transistors, and the first and the second pull amplifier elements are n-channel field effect transistors.

In Example 38, the subject matter of Example 37 includes, wherein the first and the second input nodes are connected to gates of the field effect transistors of the first push and the first pull amplifier elements, and wherein the common inter-stage input node is connected to gates of the field effect transistors of the second push and the second pull amplifier elements.

In Example 39, the subject matter of Examples 36-38 includes, wherein the first input node is coupled to at least one transient protection network.

In Example 40, the subject matter of Examples 36-39 includes, wherein the at least one transient protection network includes an electrostatic discharge (ESD) protection subcircuit and an additional transient protection subcircuit.

In Example 41, the subject matter of Examples 36-40 includes, wherein the first push-pull amplification stage and the second push-pull amplification stage are each configured to amplify signals in the 5 GHz-6 GHz frequency range.

In Example 42, the subject matter of Examples 36-41 includes, a switchable bypass circuit path to selectively bypass the second push-pull amplification stage.

In Example 43, the subject matter of Example 42 includes, a switchable path interrupter to open the feedback path when the switchable bypass circuit path is activated.

In Example 44, the subject matter of Example 43 includes, a switchable input path to couple the second input node of the first push amplifier to the first input node when the switchable bypass circuit path is activated.

In Example 45, the subject matter of Example 44 includes, a switchable inter-stage separator to decouple the common inter-stage input node from the common output node when the switchable bypass circuit path is activated.

In Example 46, the subject matter of Example 45 includes, a reactive coupling network arranged to selectively adjust input impedance at the first input node in response to a control signal.

In Example 47, the subject matter of Examples 45-46 includes, a controller subcircuit to generate a control signal to selectively activate or deactivate the switchable bypass circuit, the switchable path interrupter, the switchable input path, and the switchable inter-stage separator in response to an indication of a change in frequency band of RF signal reception operation.

In Example 48, the subject matter of Example 47 includes, wherein the controller subcircuit is configured to receive an indication of a frequency band in which the RF signal reception operation is to be carried out, and wherein the control signal is based on the indication of the frequency band.

Example 49 is a wireless communication device comprising: RF circuitry that includes, a plurality of RF chains; a baseband circuitry; and the RF amplifier circuit according to any one of Examples ckta1-11.

In Example 50, the subject matter of Example 49 includes, an antenna array.

In Example 51, the subject matter of Examples 49-50 includes, application circuitry configured to carry out user equipment (UE) functionality in accordance with the wireless communication network.

In Example 52, the subject matter of Examples 49-51 includes, application circuitry configured to carry out base station functionality in accordance with the wireless communication network.

Example 53 is a radio-frequency (RF) amplifier circuit comprising: a signal input means; a first push-pull amplification stage including a first push amplification means and a first pull amplification means, the first pull amplification means having a first input means being coupled to the signal input means and the first push amplification means having a second input means that is not coupled to the signal input means, wherein the first push amplification means and the first pull amplification means are coupled at a common output node; and a second push-pull amplification stage including a second push amplification means and a second pull amplification means, the second push-pull amplification stage including a common inter-stage input means that is coupled to the common output node, and a signal output means that is coupled to the second input means of the first push amplification means via feedback means.

In Example 54, the subject matter of Example 53 includes, wherein the first and the second push amplification means are p-channel field effect transistors, and the first and the second pull amplification means are n-channel field effect transistors.

In Example 55, the subject matter of Example 54 includes, wherein the first and the second input means are connected to gates of the field effect transistors of the first push and the first pull amplification means, and wherein the common inter-stage input means are connected to gates of the field effect transistors of the second push and the second pull amplification means.

In Example 56, the subject matter of Examples 53-55 includes, wherein the first input means are coupled to at least one transient protection means.

In Example 57, the subject matter of Examples 53-56 includes, wherein the at least one transient protection means include an electrostatic discharge (ESD) protection subcircuit and an additional transient protection means.

In Example 58, the subject matter of Examples 53-57 includes, wherein the first push-pull amplification stage and the second push-pull amplification stage are each configured to amplify signals in the 5 GHz-6 GHz frequency range.

In Example 59, the subject matter of Examples 53-58 includes, a switchable bypass means to selectively bypass the second push-pull amplification stage.

In Example 60, the subject matter of Example 59 includes, a switchable path interruption means to open the feedback means when the switchable bypass circuit path is activated.

In Example 61, the subject matter of Example 60 includes, a switchable input means to couple the second input node of the first push amplifier to the first input node when the switchable bypass means are activated.

In Example 62, the subject matter of Example 61 includes, a switchable inter-stage separation means to decouple the common inter-stage input node from the common output node when the switchable bypass means are activated.

In Example 63, the subject matter of Example 62 includes, reactive coupling means arranged to selectively adjust input impedance at the first input means in response to control means.

In Example 64, the subject matter of Examples 62-63 includes, means for generating a control signal to selectively activate or deactivate the switchable bypass means, the switchable path interrupter means, the switchable input means, and the switchable inter-stage separation means in response to an indication of a change in frequency band of RF signal reception operation.

In Example 65, the subject matter of Example 64 includes, wherein the means for generating a control signal are configured to receive an indication of a frequency band in which the RF signal reception operation is to be carried out, and wherein the control signal is based on the indication of the frequency band.

Example 66 is a method for operating a radio-frequency (RF) amplifier circuit, the method comprising: receiving, by a controller circuit, an indication of a frequency band in which RF communications are to be received; determining, by the controller circuit, an amplifier configuration from among a single-stage configuration and a multistage configuration for the RF amplifier circuit; and generating, by the controller circuit, switch control signaling to selectively enable or bypass a second amplification stage of the RF amplifier circuit.

In Example 67, the subject matter of Example 66 includes, wherein the indication of the frequency band is indicative of a relatively lower frequency band or a relatively higher frequency band; and wherein the switch control signaling is to enable the second amplification stage in response to the indication of the frequency band being indicative of the relatively higher frequency band; and wherein the switch control signaling is to bypass the second amplification stage in response to the indication of the frequency band being indicative of the relatively lower frequency band.

In Example 68, the subject matter of Examples 66-67 includes, generating, by the controller circuit, input impedance correction control signaling.

Example 69 is at least one machine-readable medium comprising instructions that, when executed by a controller subcircuit of a radio-frequency (RF) amplifier circuit, cause the RF amplifier circuit to: receive an indication of a frequency band in which RF communications are to be received; determine an amplifier configuration from among a single-stage configuration and a multistage configuration for the RF amplifier circuit; and generate switch control signaling to selectively enable or bypass a second amplification stage of the RF amplifier circuit.

In Example 70, the subject matter of Example 69 includes, wherein the indication of the frequency band is indicative of a relatively lower frequency band or a relatively higher frequency band; and wherein the switch control signaling is to enable the second amplification stage in response to the indication of the frequency band being indicative of the relatively higher frequency band; and wherein the switch control signaling is to bypass the second amplification stage in response to the indication of the frequency band being indicative of the relatively lower frequency band.

In Example 71, the subject matter of Examples 69-70 includes, wherein the instructions are to further cause the RF amplifier circuit to: generate input impedance correction control signaling.

Example 72 is at least one machine-readable medium including instructions that, when executed by processing circuitry, cause the processing circuitry to perform operations to implement of any of Examples 1-71.

Example 73 is an apparatus comprising means to implement of any of Examples 1-71.

Example 74 is a system to implement of any of Examples 1-71.

Example 75 is a method to implement of any of Examples 1-71.

The above detailed description includes references to the accompanying drawings, which form a part of the detailed description. The drawings show, by way of illustration, specific examples that may be practiced. These examples are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Publications, patents, and patent documents referred to in this document are incorporated by reference herein in their entirety, as though individually incorporated by reference. In the event of inconsistent usages between this document and those documents so incorporated by reference, the usage in the incorporated reference(s) are supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other examples may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as examples may feature a subset of said features. Further, examples may include fewer features than those disclosed in a particular example. Thus, the following claims are hereby incorporated into the Detailed Description, with a claim standing on its own as a separate example. The scope of the examples disclosed herein is to be determined with reference to the appended claims, along with the full scope of equivalents to which such claims are entitled.

1. A radio-frequency (RF) amplifier circuit for carrier-aggregation (C A) operation in a wireless communication network, the RF amplifier circuit comprising:
an input node;
a first amplifier subcircuit operably coupled to the input node, and a second amplifier subcircuit operably coupled to the input node, the first amplifier subcircuit to amplify a first RF carrier to produce a first output, and the second amplifier subcircuit to amplify a second RF carrier to produce a second output, wherein the first RF carrier and the second RF carrier are to be received simultaneously;
an amplifier subcircuit selector to selectively enable operation of the first amplifier subcircuit, the second amplifier subcircuit, or the first and the second amplifier subcircuits together, in response to a selection indication, and
a reactive coupling network arranged to selectively adjust the input impedance at the input node in response to the selection indication to reduce the input impedance variation.

2. The RF amplifier circuit of claim 1, wherein various enablement configurations of the first and the second amplifier subcircuits are associated with input impedance variation at the input node.

3. The RF amplifier circuit of claim 1, wherein the first RF carrier and the second RF carrier are among a defined band of frequencies within the wireless communication network.

4. The RF amplifier circuit of claim 1, wherein the first amplifier subcircuit and the second amplifier subcircuit are each a low-noise amplifier (LNA).

5. The RF amplifier circuit of claim 1, wherein the reactive coupling network includes a control signal input to receive an adjustment signal corresponding to a desired input impedance, wherein the desired input impedance is based on the selection indication.

6. The RF amplifier circuit of claim 5, further comprising:
a controller subcircuit to produce:
a selection control signal that includes the selection indication; and
the adjustment signal.

7. The RF amplifier circuit of claim 1, wherein the reactive coupling network includes a control signal input to receive an adjustment signal corresponding to a quantity of amplifier subcircuits that are to be selectively enabled.

8. The RF amplifier circuit of claim 7, wherein the adjustment signal corresponds further to a particular set of frequencies of the first RF carrier and the second RF carrier.

9. The RF amplifier circuit of claim 1, wherein the input node is coupled to an input source having a source impedance, and wherein the input impedance variation causes variation in return loss as experienced by the input source; and wherein the reactive coupling network is to reduce the return loss by matching input impedance to the source impedance.

10. The RF amplifier circuit of claim 1, wherein the first RF carrier is a first component carrier having a first plurality of subcarriers, and the second RF carrier is a component carrier having a second plurality of subcarriers.

11. The RF amplifier circuit of claim 1, wherein first amplifier subcircuit and the second amplifier subcircuit are constructed to operate in the frequency range of 1.8 GHz -2.7 GHz.

12. The RF amplifier circuit of claim 1, wherein the first amplifier subcircuit and the second amplifier subcircuit include complementary metal-oxide-semiconductor (CMOS) transistors.

13. The RF amplifier circuit of claim 1, wherein the reactive coupling network includes a variable capacitance.

14. The RF amplifier circuit of claim 1, wherein the reactive coupling network is configured to produce a variable time constant.

15. The RF amplifier circuit of claim 1, wherein the reactive coupling network includes a variable resistor-capacitor combination in a shunt configuration coupled to the input node.

16. The RF amplifier circuit of claim 13, wherein the variable resistor-capacitor combination includes a variable resistor.

17.-21. (canceled)

22. A method for operating a radio-frequency (RF) amplifier circuit facilitating carrier-aggregation (CA) operation in a wireless communication network, the method comprising:
receiving, by a controller circuit, an indication of carriers for use in the CA operation;
generating, by the controller circuit, an amplifier subcircuit selection indication indicating amplifier subcircuits to be selectively enabled from among at least a first amplifier subcircuit, and a second amplifier subcircuit, the amplifier subcircuit selection indication being based on the indication of carriers; determining, by the controller circuit, an input impedance correction for a common input node of the first amplifier subcircuit and the second amplifier subcircuit, based on the amplifier subcircuits to be selectively enabled; and
generating, by the controller circuit, an input impedance adjustment signal representing electrical operations to be performed to effect the input impedance correction.

23. The method of claim 22, wherein the electrical operations include variation of capacitance of the common input node.

24. A non-transitory machine-readable medium comprising instructions that, when executed by a controller circuit of a radio-frequency (RF) amplifier facilitating carrier-aggregation (CA) operation in a wireless communication network, causes the RF amplifier to:
receive an indication of carriers for use in the CA operation;
generate an amplifier subcircuit selection indication indicating amplifier subcircuits to be selectively enabled from among at least a first amplifier subcircuit, and a second amplifier subcircuit, the amplifier subcircuit selection indication being based on the indication of carriers;
determine an input impedance correction for a common input node of the first amplifier subcircuit and the second amplifier subcircuit, based on the amplifier subcircuits to be selectively enabled; and
generate an input impedance adjustment signal representing electrical operations to be performed to effect the input impedance correction.

25. The non-transitory machine-readable medium of claim 24, wherein the electrical operations include variation of capacitance of the common input node.
